(19) United States
(12) Patent Application Publication
(10) Pub. No.: US 2026/0040572 A1
(43) Pub. Date: Feb. 5, 2026

(54) SEMICONDUCTOR DEVICE AND METHOD FOR FABRICATING THE SAME

(71) Applicant: United Microelectronics Corp., Hsinchu (TW)

(72) Inventor: Ching-Hua HSU, Kaohsiung City (TW)

(21) Appl. No.: 18/817,283

(22) Filed: Aug. 28, 2024

(30) Foreign Application Priority Data
Aug. 2, 2024 (TW) 113128900

(51) Int. Cl. H10B 61/00

(52) U.S. Cl. CPC H10B 61/00

(57) ABSTRACT

A semiconductor device includes a substrate, a first dielectric layer, a second dielectric layer and a capping stop layer. The substrate includes a memory region and a logic region, wherein the memory region includes a memory array. The first dielectric layer covers the memory region; the second dielectric layer covers the logic region. The capping stop layer is disposed above the first dielectric layer and having a capping pattern at least covering a boundary between the memory region and the logic region.

This application claims the benefit of Taiwan Application Serial No. 113128900 filed at Aug. 2, 2024 the subject matter of which is incorporated herein by reference.

### BACKGROUND

### Technical Field

The disclosure relates to a semiconductor device and the method for fabricating the same, and more particularly to a composite semiconductor device having both a memory region and a logic region and the method for fabricating the same.

### Description of Background

With the development of integrated circuit (IC) technology, composite semiconductor devices both having memory arrays and logic units have become one of the important components for constituting integrated circuits. To take a composite semiconductor device both having an embedded non-volatile memory (NVM) array (such as a resistive random-access memory (ReRAM) array or a magnetoresistive random access memory (MRAM) array) and a logic control unit as an example, since the embedded NVM array and the logic control unit have different device thicknesses, thus there is a height difference between the memory region used to form the embedded NVM array and the logic region used to form the logic control unit, which may adversely affect the yield of the subsequent back-end processes performed above these two.

In order to achieve the purpose of evening the height difference between the memory region and the logic region, the prior art would perform steps as follows: A dielectric layer with a thickness greater than this height difference is formed directly on the semiconductor substrate (for example, a wafer) to cover the memory region and logic region at the same time. A photoresist etching back process is then performed to remove a portion of the dielectric layer covering the memory region with a height. Subsequently, the top surface of the remaining dielectric layer is planarized by a polishing process.

Considering the polishing margin of the subsequent polishing process, when performing the photoresist etching back process, the portion of the dielectric layer above the boundary of the memory region and the logic region would be generally remained with a larger thickness. However, since it is difficult to control the local etching depth during the photoresist etching back process, thus highly uneven bumps may form in the etched dielectric layer, which may easily cause the remained dielectric layer to be damaged and crack due to stress during the subsequent polishing process. Uneven and broken. And the combination of these factors is likely to cause local depressions, wiring interruptions or circuits short in the subsequent metal conductor structures formed above the dielectric layer, and even damage the memory arrays.

Therefore, there is a need of providing a semiconductor device and the method for fabricating the same to obviate the drawbacks encountered from the prior art.

### SUMMARY

One aspect of the present disclosure is to provide a semiconductor device, wherein the semiconductor device includes a substrate, a first dielectric layer, a second dielectric layer and a capping stop layer. The substrate includes a memory region and a logic region, wherein the memory region includes a memory array. The first dielectric layer covers the memory region; the second dielectric layer covers the logic region. The capping stop layer is disposed above the first dielectric layer and having a capping pattern at least covering a boundary between the memory region and the logic region.

Another aspect of the present disclosure is to provide a method for fabricating a semiconductor device, which includes the following steps: Firstly, a substrate is provided to make the substrate including a memory region and a logic region, wherein the memory region includes a memory array. Afterwards, a first dielectric layer is formed to cover the memory region and the logic region. A capping stop layer is then formed to cover the first dielectric layer. Next, an etching process is performed to remove a portion of the first dielectric layer and a portion of the capping stop layer both disposed above the logic region; and a second dielectric layer is formed to cover the memory region and the logic region. After etching and removing a portion of the second dielectric layer disposed above the memory region, a planarization process is performed on the memory region and the logic region using the capping stop layer as a polishing stop layer.

In accordance with the aforementioned embodiments of the present disclosure, a semiconductor device and a fabricating method thereof are provided. Firstly, a substrate including a memory region and a logic region is provided, wherein the memory region includes a memory array. Then, a first dielectric layer is formed to cover the memory a region and the logic region, wherein the portion of the first dielectric layer covering the memory region is higher than the portion of the first dielectric layer covering the logic region. Next, a capping stop layer whose composition is different from that of the first dielectric layer is formed on the first dielectric layer. After a portion of the first dielectric layer and a portion of the capping stop layer both covering the logic region are removed by an etching process, a second dielectric layer is formed to cover the memory region and the logic region; and then a portion of the second dielectric layer covering the memory region is removed through another etching process. Subsequently, a planarization process is performed on the memory region and the logic region, using the capping stop layer as a polishing stop layer, to remain at least a portion of the capping stop layer on the peripheral area of the memory region.

By adding a capping stop layer between the two dielectric layers to be planarized on the memory region, the polishing thickness of the planarization process can be accurately controlled to retain a proper polishing margin for the planarization process. While the height different between the memory region and the logic region can be evened without damaging the memory array disposed in the memory region.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A to FIG. 1G are diagrams illustrating a series of process structures for producing of a semiconductor device, according to one embodiment of the present disclosure; and

FIG. 2 is a top view illustrating the process structure after the planarization process is performed based on FIG. 1G.

### DETAILED DESCRIPTION

The embodiments as disclosed below provide a semiconductor device and the method for fabricating the same, which can even the height different between the memory region and the logic region, while not damage the memory array disposed in the memory region. Such that it can greatly improve the yield and process efficiency of semiconductor devices. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

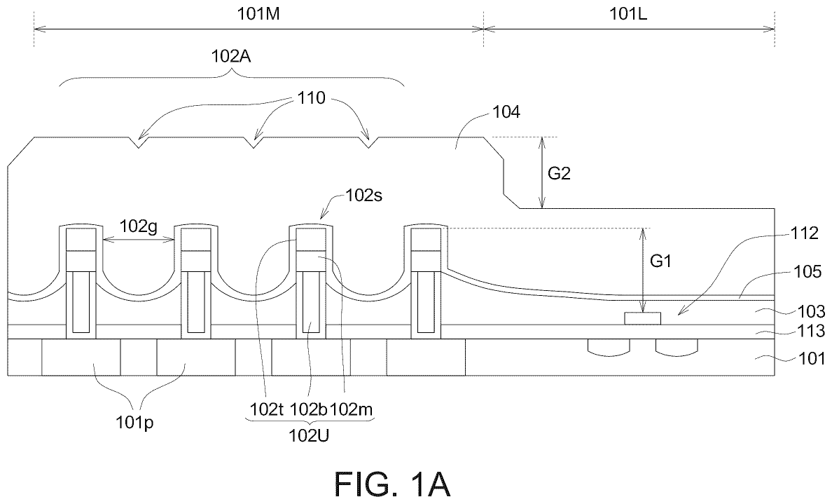

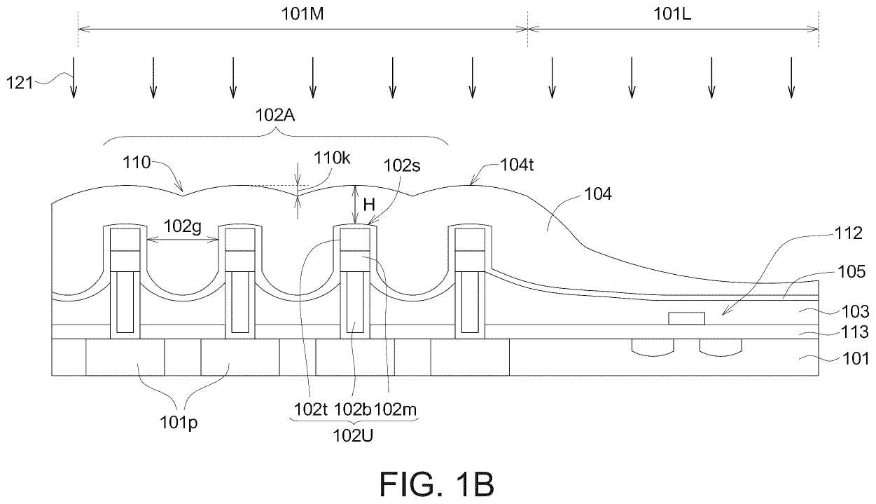

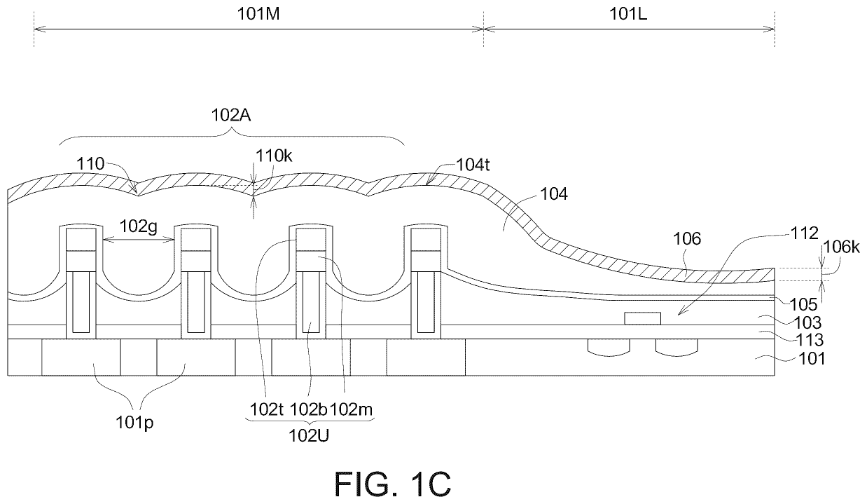

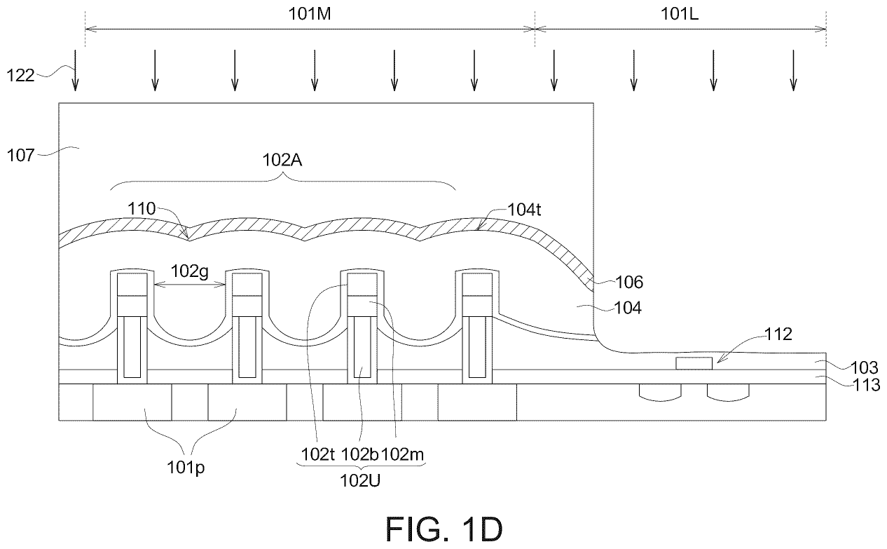

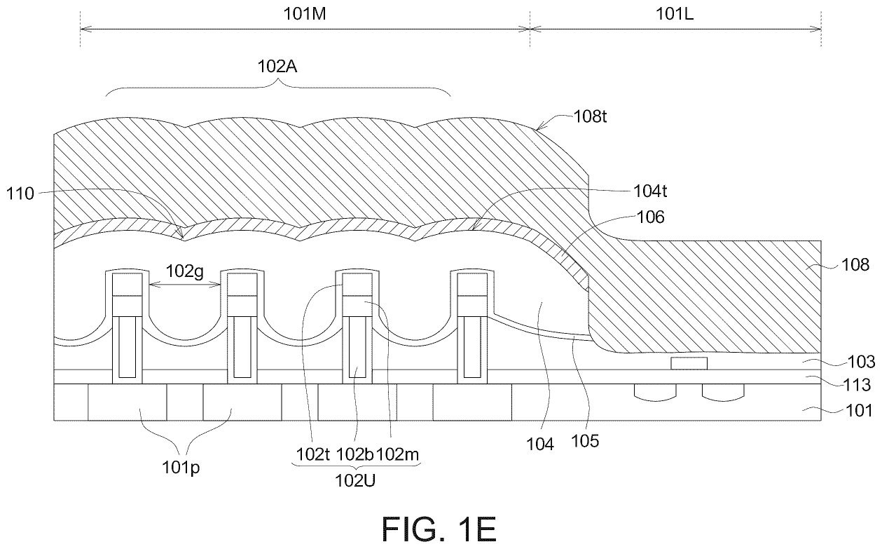

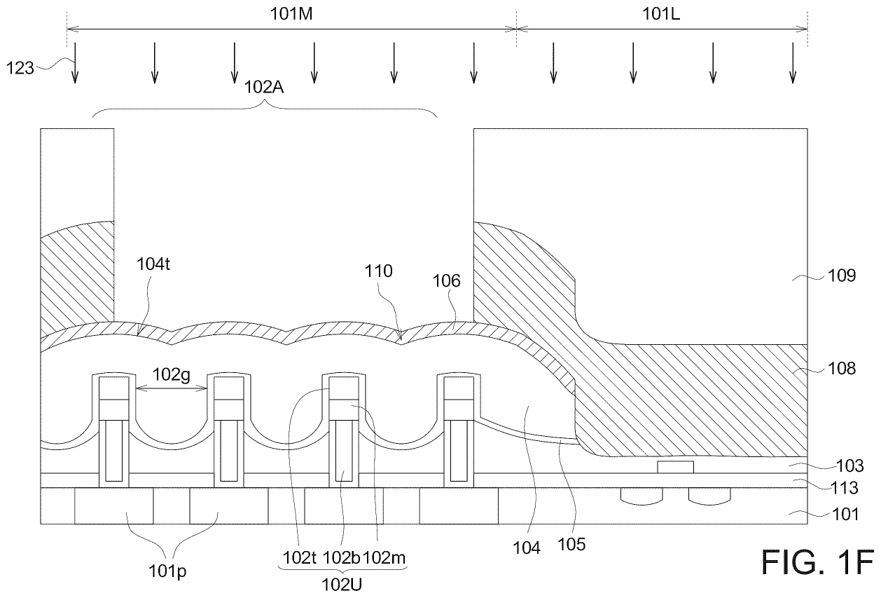

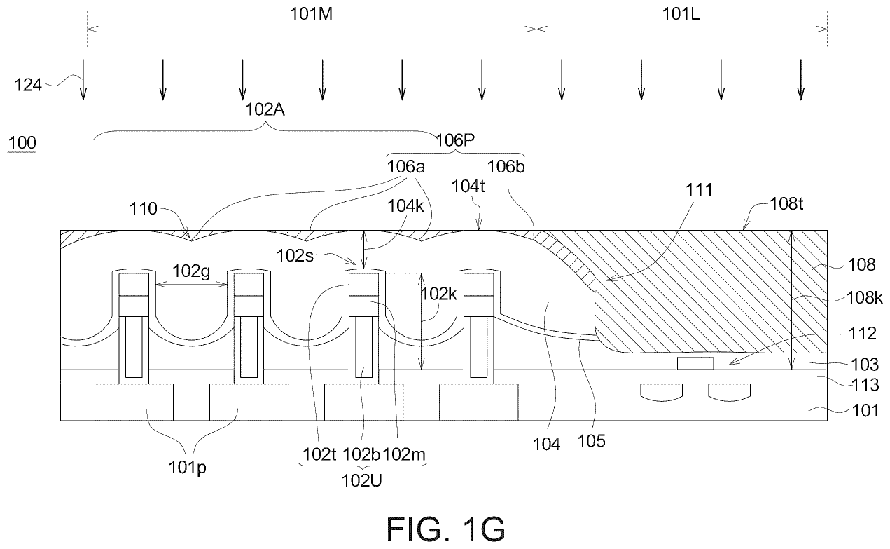

FIG. 1A to FIG. 1G are diagrams illustrating a series of process structures for producing of a semiconductor device 100, according to one embodiment of the present disclosure. In some embodiments of the present disclosure, the semiconductor device 100 may be a composite semiconductor device with an embedded memory array (such as, a ReRAM array, a MRAM array, or other non-volatile/volatile memory arrays) and logic control units.

The fabricating method of the semiconductor deice 100 includes the following steps: First, a semiconductor substrate 101 including a memory region 101M and a logic region 101L is provided, wherein the memory region 101M includes a memory array 101A; and the logic region 101L includes at least one transistor cell 112. There is a height difference G1 between the top of the memory array 101A disposed in the memory region 101M and the top of the transistor unit 112 disposed in the logic region 101L (as shown in FIG. 1A).

In some embodiments of the present disclosure, the semiconductor substrate 101 may be a silicon-containing substrate, such as, a silicon wafer or a silicon-on-insulator (SOI) substrate. In some other embodiments of the present disclosure, the semiconductor substrate 101 may be made of other types of semiconductor material (such as, germanium (Ge)), or compound semiconductor material (such as, gallium arsenide (GaAs)). In the present embodiment, the semiconductor substrate 101 may be a silicon wafer.

In some embodiments of the present disclosure, the memory array 102A disposed in the memory region 101M may be an array structure composed of a plurality of ReRAM cells 102U. Each of the ReRAM cell 102U includes an upper conductive plug 102t, a lower conductive plug 102b and a memory layer 102m. The lower conductive plug 102b passes through an interlayer dielectric layer 103 and a dielectric isolation layer 113 both disposed above the semiconductor substrate 101 and electrically contacts to the pad of a patterned conductive layer 101p disposed in the semiconductor substrate 101. The memory layer 102m is disposed above and electrically contacts with the lower conductive plug 102b; and the upper conductive plug 102t is disposed above and electrically contacts with the memory layer 102m.

In the present embodiment, the material constituting the lower conductive plug 102b may be tungsten (W), copper (Cu), titanium (Ti), titanium nitride (TiN), aluminum (Al), nickel (Ni), zirconium (Zr), niobium (Nb), tantalum (Ta), ytterbium (Yb), terbium (Tb), yttrium (Y), rhodium (La), scandium (Sc), hafnium (Hf), chromium (Cr), vanadium (V), zinc (Zn), molybdenum (Mo), rhenium (Re), ruthenium (Ru), cobalt (Co), rhodium (Rh), cadmium (Pd), platinum (Pt) or an alloy composed of any combination thereof. The material constituting the upper conductive plug 102t may be the same or a different material than the lower conductive plug 102b.

The memory layer 102m may be a transition metal oxide layer and may be composed of a metal oxide compound represented by the chemical formula AOx, where A is selected from the group consisting of W, Ti, TiN, Al, Ni, Cu, Zr, Nb, Ta and any combination thereof. For example, the metal oxide compound can be Hafnium Oxide (HfOx), Zirconium Oxide (ZrOx), Aluminum Oxide (AlOx), Nickel Oxide (NiOx), Tantalum Oxide (TaOx), titanium oxide (TiOx) or any combination thereof.

However, the memory array 102A may not be limited to this regard. In other embodiments of the present disclosure, the memory array 102A may be an array structure composed of a plurality of MRAM units 102U. The memory layer 102m of each MRAM unit 102U includes an upper electrode layer (an upper conductive plug 102t), a first magnetic layer, a magnetic tunneling oxide layer, a second magnetic layer and a lower electrode layer (a lower conductive plug 102b), which are staked in a sequential manner and combined to form a magnetic tunneling junction (MTJ) structure.

The conductive material constituting the upper electrode layer (the upper conductive plug 102t) may include (but is not limited to) Ru, Ta, Pt, Cu, gold (Au), Al or an arbitrary combination thereof. The material constituting the lower electrode layer (the lower conductive plug 102b) may include one of Ta, W, Pt, Co, Ru, or an arbitrary combination thereof. The material constituting the first magnetic layer and the second magnetic layer may include an iron-containing magnetic material, such as cobalt iron boron (CoFeB). The material constituting the magnetic tunneling oxide layer may include one of magnesium oxide (MgO), AlOx, HfOx, or an arbitrary combination thereof.

Afterwards, a first dielectric layer 104 is formed to cover the memory region 101M and the logic region 101L. Wherein, the portion of the first dielectric layer 104 covering the memory array 102A is higher than another portion of the first dielectric layer 104 covering the logic region 101L. That is, there is a height difference G2 between the top of the portion of the first dielectric layer 104 covering the memory region 101M and the top of the portion of the first dielectric layer 104 covering the logic region 101L.

In the present embodiment, although a portion of the first dielectric layer 104 may be inserted into the gap 102g between two adjacent MRAM units 102U, but the thickness of the first dielectric layer 104 is not enough to fill the gap 102g between the two adjacent MRAM units 102U, thus at least one recess 110 can be form on a location on the top surface 104t of the first dielectric layer 104 corresponding to the gap 102g and over the memory array 102A (as shown in FIG. 1A).

In some embodiments of the present disclosure, the first dielectric layer 104 may be a silicon oxide (SiOₓ) layer formed on the semiconductor substrate 101 by deposition. The first dielectric layer 104 covers the memory array 102A disposed in the memory region 101M and the transistor unit 112 disposed in the logic region 101L. In the present embodiment, before forming the first dielectric layer 104, a low-pressure chemical vapor deposition (CVD) process is preferably performed to form a dielectric blanket layer 105 to cover the memory array 102A and the transistor unit 112. The material constituting the dielectric blanket layer 105 may be silicon nitride (SiN), aluminum nitride (AlN), silicon oxynitride (SiON) or an arbitrary combination thereof.

Then, an etching back process 121 is performed to thin the thickness of the first dielectric layer 104, so as to make the top surface 102s of the memory array 102A separated from the top surface 104t of the first dielectric layer 104 for a distance H. And the distance H is greater than the depth 110k of the recess 110 (as shown in FIG. 1B).

Next, a capping stop layer 106 is formed on the first dielectric layer 104 to cover the memory region 101M and the logic region 101L. The thickness 106k of the capping stop layer 106 is greater than the depth 110k of the recess 110 formed on the top surface 104t of the first dielectric layer 104 (as shown in FIG. 1C). In some embodiments of the present disclosure, the thickness 106k of the capping stop layer 106 may substantially range from 1 nanometer (nm) to 100 nm; preferably may substantially range from 5 nm to 50 nm.

The material constituting the capping stop layer 106 may be a dielectric material different from the composition constituting the first dielectric layer 104. For example, in some embodiments of the present disclosure, the material constituting the capping stop layer 106 may include SiN, silicon carbide (SiC), silicon carbonitride (SiCN), silicon oxycarbide (SiCO), or an arbitrary combination thereof. In the present embodiment, the dielectric material constituting the first dielectric layer 104 may include silicon dioxide (SiO₂); and the dielectric material constituting the capping stop layer 106 may include SiN.

Then, a portion of the first dielectric layer 104 and a portion of the covering stop layer 106 both disposed above the logic region 101L are removed by an etching process 122. In some embodiments of the present disclosure, a patterned photoresist layer 107 can be formed on the semiconductor substrate 101 (covering the portion of the capping stop layer 106 disposed on the memory region 101M) to expose the portion of the capping stop layer 106 disposed above the logic region 101L, and then an anisotropic etching (e.g., an dry etching) process 122 is performed to remove the exposed portion of the capping stop layer 106 and portions of the dielectric capping layer 105 and the first dielectric layer 104 both beneath the exposed portion of the capping stop layer 106. (As shown in FIG. 1D).

A second dielectric layer 108 is then formed to cover the memory region 101M and the logic region 101L. The material constituting the second dielectric layer 108 may be different from the material constituting the capping stop layer 106. For example, in some embodiments of the present disclosure, the material constituting the second dielectric layer 108 may be the same as the material constituting the first dielectric layer 104. In the present embodiment, both of the first dielectric layer 104 and the second dielectric layer 108 are SiO₂ layers (shown in FIG. 1E).

Afterwards, as shown in FIG. 1F, another etching process 123 using a patterned photoresist layer 109 as an etching mask is performed to remove a portion of the second dielectric layer 108 disposed above the memory region 101M, so as to expose a portion of the covering stop layer 106 disposed above the memory region 101M.

Next, a planarization process 124, using the capping stop layer 106 as a polishing stop layer, is performed on the memory region 101M and the logic region 101L to remove a portion of the second dielectric layer 108 disposed above the memory region 101M and most portion of the stop layer 106 disposed above the memory region 101M, so as to expose a portion of the first dielectric layer 104 disposed above the memory region 101M. During the planarization process 124, there is a polishing selectivity ratio ranging from 5/1 to 10/1 for removing the capping stop layer 106 and the first dielectric layer 104.

As shown in FIG. 1G, the upper surface 104t of the exposed portion of the first dielectric layer 104 and the upper surface 108t of the portion of the second dielectric layer 108 disposed above the logic region 101L are substantially coplanar. In other words, after the planarization process 124 is performed, the exposed portion of the first dielectric layer 104 has a first remaining thickness 104k measured from the top surface 102s of the MRAM units 102U; the portion of the second dielectric layer 108 disposed above the logic region 101L has a second remaining thickness 108k; and the second remaining thickness 108k is equal to the sum of the height 102k of the MRAM units 102U and the first remaining thickness 104k (108k=102k+104k).

In some embodiments of the present disclosure, the planarization process 124 does not remove all of the capping stop layer 106 disposed above the memory region 101M, but leaves a filling portion 106a of the capping layer 106 to fill in the bottom of the recess 110 located above the memory region 101M; and leaves another filling portion 106b of the capping layer 106 to fill in the bottom of the recess 110 located in a peripheral area 111 of the memory region 101M (i.e., the boundary of the memory region 101M and the logic region 101L). And the filling portions 106a and 106b of the remained capping stop layer 106 are combined to form a capping pattern 106P.

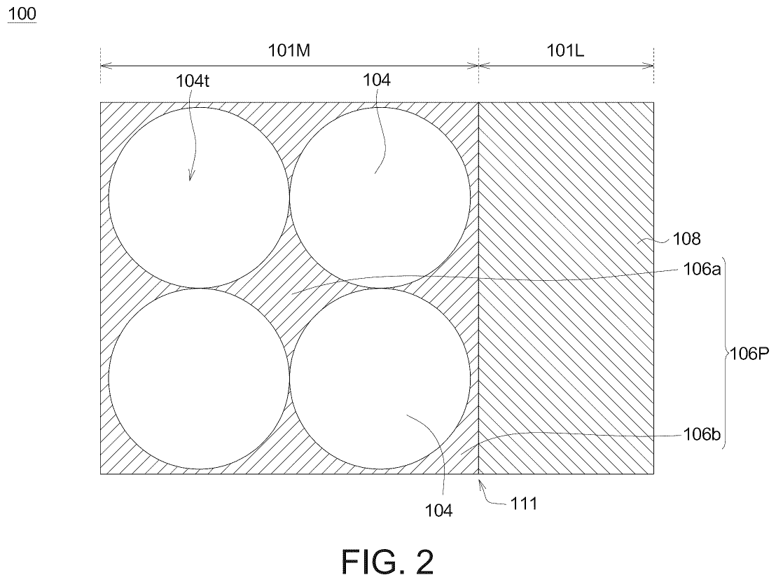

FIG. 2 is a top view illustrating the process structure after the planarization process 124 is performed based on FIG. 1G. In the present embodiment, the capping pattern 106P formed by the filling portions 106a and 106b of the remaining capping stop layer 106 substantially surrounds the peripheral area 111 of the memory region 101M.

By adding the capping stop layer 106, the polishing thickness of the planarization process 124 can be accurately controlled, so as to retain a proper polishing margin for the planarization process 124. While, the height difference between the portion of the first dielectric layer 104 covering the memory 101M and the portion of the second dielectric layer 108 covering the logic region 101L can be evened without damaging the memory array 102A disposed in the memory region 101M.

Subsequently, a series of downstream processes (such as, a metal damascene process) are performed to at last form an interconnect structure (not shown) on the planarized first dielectric layer 104 and the second dielectric layer 108 respectively disposed on the logic region 101L and the memory region 101M to complete the preparation of the semiconductor device 100 as shown in FIG. 1G.

In accordance with the aforementioned embodiments of the present disclosure, a semiconductor device and a fabricating method thereof are provided. Firstly, a substrate including a memory region and a logic region is provided, wherein the memory region includes a memory array. Then, a first dielectric layer is formed to cover the memory a region and the logic region, wherein the portion of the first dielectric layer covering the memory region is higher than the portion of the first dielectric layer covering the logic region. Next, a capping stop layer whose composition is different from that of the first dielectric layer is formed on the first dielectric layer. After a portion of the first dielectric layer and a portion of the capping stop layer both covering the logic region are removed by an etching process, a second dielectric layer is formed to cover the memory region and the logic region; and then a portion of the second dielectric layer covering the memory region is removed through another etching process. Subsequently, a planarization process is performed on the memory region and the logic region, using the capping stop layer as a polishing stop layer, to remain at least a portion of the capping stop layer on the peripheral area of the memory region.

By adding a capping stop layer between the two dielectric layers to be planarized on the memory region, the polishing thickness of the planarization process can be accurately controlled to retain a proper polishing margin for the planarization process. While the height different between the memory region and the logic region can be evened without damaging the memory array disposed in the memory region.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for fabricating a semiconductor device, comprising:
providing a substrate comprising a memory region and a logic region, wherein the memory region includes a memory array;
forming a first dielectric layer coving the logic region and the memory region;
forming a capping stop layer coving the logic region;
performing an etching process to remove a portion of the first dielectric layer and a portion of the capping stop layer both disposed above the logic region;
forming a second dielectric layer to cover the logic region and the memory region;
etching and removing a portion of the second dielectric layer disposed above the memory region; and
performing a planarization process on the memory region and the logic region using the capping stop layer as a polishing stop layer.

2. The method according to claim 1, wherein a portion of the first dielectric layer covering the memory array is higher than a portion of the first dielectric layer covering the logic region.

3. The method according to claim 1, wherein the capping stop layer has a material different from that of the first dielectric layer.

4. The method according to claim 3, wherein there is a polishing selectivity ratio ranging from 5/1 to 10/1 for removing the capping stop layer and the first dielectric layer.

5. The method according to claim 3, wherein the capping stop layer comprises silicon nitride (SiN); the first dielectric layer comprises silicon oxide (SiOₓ).

6. The method according to claim 3, wherein after performing the planarization process, at least a portion of the covering stop layer is remained in a peripheral area of the memory region.

7. The method according to claim 6, wherein the memory array has a memory unit height; after performing the planarization process, there is a first remaining thickness between the first dielectric layer and the memory array; the second dielectric layer has a second remaining thickness; and the second remaining thickness is equal to a sum of the memory unit height and the first remaining thickness.

8. The method according to claim 1, wherein after forming the first dielectric layer, there is a height difference between the portion of the first dielectric layer covering the memory region and the portion of the first dielectric layer covering the logic region; and at least one recess is form on a top surface of the first dielectric layer over the memory array.

9. The method according to claim 8, wherein the capping stop layer has a thickness greater than a depth of the at least one recess.

10. The method according to claim 8, wherein the thickness of the capping stop layer substantially ranges from 1 nanometer (nm) to 100 nm.

11. The method according to claim 8, before forming the capping stop layer, further comprising performing an etching back process to make a top surface of the memory array separated from a top surface of the first dielectric layer for a distance greater than a depth of the at least one recess.

12. A semiconductor device, comprising:
a substrate comprising a memory region and a logic region, wherein the memory region includes a memory array;
a first dielectric layer the memory region;
a second dielectric layer, covering the logic region; and
a capping stop layer, disposed above the first dielectric layer and having a capping pattern at least covering a boundary between the memory region and the logic region.

13. The semiconductor device according to claim 12, wherein the capping stop layer has a top view pattern substantially surrounding a peripheral area of the memory region.

14. The semiconductor device according to claim 12, wherein the memory array has a memory unit height; there is a first remaining thickness between the first dielectric layer and the memory array; the second dielectric layer has a second remaining thickness; and the second remaining thickness is equal to a sum of the memory unit height and the first remaining thickness.

15. The semiconductor device according to claim 12, wherein at least one recess is form on a top surface of the first dielectric layer over the memory array; and the capping pattern comprises at least one filling portion filled in the at least one recess.
